(19) United States
(12) Patent Application Publication
(10) Pub. No.: US 2026/0190615 A1
(43) Pub. Date: Jul. 2, 2026

(54) DISPLAY DEVICE

(71) Applicant: LG Display Co., Ltd., Seoul (KR)

(72) Inventor: Sunhee LEE, Paju-si (KR)

(73) Assignee: LG Display Co., Ltd., Seoul (KR)

(21) Appl. No.: 19/391,752

(22) Filed: Nov. 17, 2025

(30) Foreign Application Priority Data
Dec. 27, 2024 (KR) 10-2024-0198523

(51) Int. Cl. H10K 50/19; H10K 50/17; H10K 101/40; H10K 102/00

(52) U.S. Cl. CPC H10K 50/19; H10K 50/17; H10K 50/171; H10K 2101/40; H10K 2102/351

(57) ABSTRACT

A display device is provided that includes a substrate having a plurality of sub-pixels, each containing a light emitting device. Each light emitting device includes a first electrode, a first stack, an n-type charge generation layer, and a p-type charge generation layer disposed in sequence. In at least one sub-pixel, an auxiliary charge generation layer is additionally provided between the n-type charge generation layer and the p-type charge generation layer. The auxiliary charge generation layer has different electrical conductivity or doping concentration from the n-type charge generation layer, thereby improving charge balance and reducing lateral leakage current between adjacent sub-pixels. This structure enhances light emission efficiency, maintains color accuracy, and improves the overall reliability of the display device while maintaining a compact pixel arrangement suitable for high-resolution applications.

### CROSS-REFERENCE TO RELATED APPLICATIONS

This application claims the benefit of the Republic of Korea Patent Application No. 10-2024-0198523 filed on December 27, 2024, each of which is hereby incorporated by reference in its entirety.

### BACKGROUND

### Technical Field

The present disclosure relates to a display device.

### Description of the Related Art

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required, and power consumption is advantageous. In addition, the organic light emitting display device has an advantage of being driven with a low DC voltage, having a fast response speed, and especially low manufacturing cost.

### BRIEF SUMMARY

As high-resolution display devices are developed, the distance between pixels becomes smaller, resulting in increased lateral leakage current (LLC) between adjacent pixels, which deteriorates display quality. The present disclosure addresses these issue by providing a light emitting device capable of reducing the generation of lateral leakage current, as well as display devices including such light emitting devices.

In particular, the disclosed display device relates to an OLED structure configured to reduce lateral leakage current between adjacent subpixels while maintaining high efficiency and operational stability. This is accomplished by introducing an auxiliary charge generation layer positioned between the n-type and p-type charge generation layers in selected subpixels. The auxiliary layer, having a higher doping concentration and greater electrical conductivity than the standard n-type layer, enhances electron supply and charge balance without increasing unwanted current flow.

Unlike conventional OLED structures that employ a single charge generation layer arrangement for all subpixels, this configuration selectively includes the auxiliary layer, for example in the green subpixel where emission efficiency is most critical. This selective arrangement effectively minimizes color distortion and light emission defects caused by leakage, while maintaining consistent electrical performance across the display.

Through adjustment of doping concentration, electrical conductivity, and energy level alignment of the charge generation layers, the structure enables smooth electron transfer, improved luminous efficiency, and reduced interference between neighboring subpixels. As a result, the display device achieves higher image quality, longer operational lifetime, and lower power consumption through a refined modification of the OLED layer stack.

In accordance with an aspect of the present disclosure, the above and other technical effects can be accomplished by the provision of a display device comprising a substrate including a first sub-pixel and a second sub-pixel, a first light emitting device in the first sub-pixel, and a second light emitting device in the second sub-pixel, wherein each of the first light emitting device and the second light emitting device includes a first electrode on the substrate, a first stack on the first electrode, an n-type charge generation layer on the first stack, and a p-type charge generation layer on the n-type charge generation layer, and wherein the first sub-pixel further includes an auxiliary charge generation layer between the n-type charge generation layer and the p-type charge generation layer.

It is to be understood that both the foregoing general description and the following detailed description are exemplary and explanatory and are intended to provide further explanation of the inventive concepts as claimed

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a plan view of a display device according to an embodiment of the present disclosure.

FIG. 2 is a plan view of one pixel according to an embodiment of the present disclosure.

FIG. 3 is a cross-sectional view of one sub-pixel according to an embodiment of the present disclosure.

FIG. 4 is a cross-sectional view of a light emitting device according to an embodiment of the present disclosure.

FIG. 5 is a circuit diagram of a light emitting device according to an embodiment of the present disclosure.

FIG. 6 is a diagram illustrating an energy band diagram of a light emitting device according to an embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art. Further, the scope of the present disclosure is only defined by of the accompanying claims.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise,’ ‘have,’ and ‘include’ described in the present disclosure are used, another portion may be added unless ‘only~’ is used. The terms of a singular form may include plural forms unless referred to the contrary.

In interpreting the components, it is interpreted as including an error range even if there is no separate explicit description of an error range.

In describing a position relationship, for example, when the position relationship is described as ‘upon~,’ ‘above~,’ ‘below~’ and ‘next to~,’ one or more portions may be disposed between two other portions unless ‘just’ or ‘direct’ is used. The terms, such as “below,” “lower,” “above,” “upper,” and the like, may be used herein to describe a relationship between elements as illustrated in the drawings. It will be understood that the terms are spatially relative and based on the orientation depicted in the drawings.

A description of a time relationship may include a case in which the temporal precedence relationship is described as “after,” “following,” or “before,” etc., and is not continuous unless “right away” or “directly,” is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b),” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

Features of each of the various examples of the present disclosure may be partially or entirely coupled or combined with each other, technically various interworking and driving are possible, and each of the examples may be independently implemented with respect to each other or may be implemented together in a related relationship.

Hereinafter, one embodiment of the present disclosure will be described in detail with reference to the accompanying drawings.

FIG. 1 is a plan view of a display device 10 according to an embodiment of the present disclosure.

Referring to FIG. 1, the display device 10 according to an embodiment of the present disclosure may include a display area DA and a non-display area NDA surrounding the display area DA. The display area DA is an area in which an image may be displayed, and the non-display area NDA is an area in which an image is not displayed.

The display area DA may include a plurality of pixels P. The plurality of pixels P may be arranged in a matrix form consisting of a plurality of rows and columns. In addition, the non-display area NDA may include a plurality of wirings, pads, driving circuits, etc., for driving the plurality of pixels P.

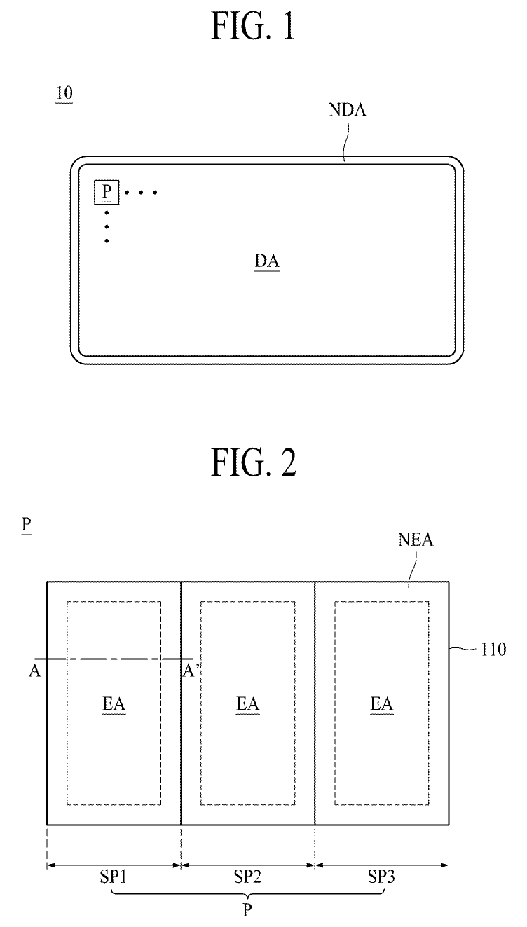

FIG. 2 is a plan view of one pixel P according to an embodiment of the present disclosure.

Referring to FIG. 2, one pixel P may include a first sub-pixel SP1, a second sub-pixel SP2, and a third sub-pixel SP3. The first sub-pixel SP1, the second sub-pixel SP2, and the third sub-pixel SP3 may emit different light from each other. For example, the first sub-pixel SP1 may emit red light, the second sub-pixel SP2 may emit green light, and the third sub-pixel SP3 may emit blue light, but the present disclosure is not limited thereto. In addition, FIG. 2 shows that one pixel P includes three sub-pixels SP1 to SP3, but is not limited thereto. For example, one pixel P may include more than three sub-pixels.

The first sub-pixel SP1, the second sub-pixel SP2, and the third sub-pixel SP3 may be disposed on the first substrate 110. Each of the first sub-pixel SP1, the second sub-pixel SP2, and the third sub-pixel SP3 may include an emission area EA and a non-emission area NEA surrounding the emission area EA. The emission area EA is an area capable of emitting light, and the non-emission area NEA is an area that does not emit light.

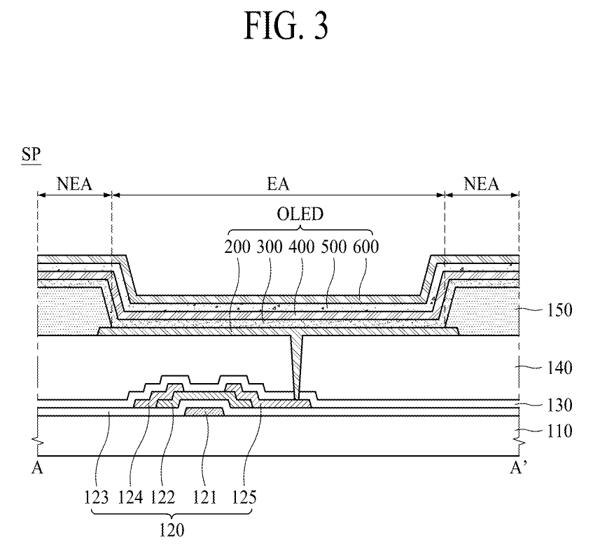

FIG. 3 is a cross-sectional view of one sub-pixel SP according to an embodiment of the present disclosure. In detail, it is a cross-sectional view of one sub-pixel SP taken along line A-A′ illustrated in FIG. 2. FIG. 3 is a cross-sectional view of the first sub-pixel SP1, but the present disclosure is not limited thereto. For example, it may be a cross-sectional view of any one of the second sub-pixel SP2 and the third sub-pixel SP3 illustrated in FIG. 2.

Referring to FIG. 3, one sub-pixel SP according to an embodiment of the present disclosure may include a first substrate 110, a thin film transistor 120, a passivation layer 130, a planarization layer 140, a bank 150, and a light emitting device OLED.

The first substrate 110 may be formed of glass or plastic, but is not limited thereto. The display device according to an embodiment of the present disclosure may be configured in a top emission type in which emitted light is emitted upward. Therefore, as a material of the first substrate 110, not only a transparent material but also an opaque material may be used.

The thin film transistor 120 may be disposed on the first substrate 110. The thin film transistor 120 may include a gate electrode 121, a semiconductor layer 122, a gate insulating layer 123, a source electrode 124, and a drain electrode 125.

The gate electrode 121 of the thin film transistor 120 may be disposed on the first substrate 110. In addition, the semiconductor layer 122 may be disposed on the gate electrode 121. The semiconductor layer 122 may include a poly-silicon semiconductor or an oxide semiconductor. In addition, when the semiconductor layer 122 includes an oxide semiconductor, at least one oxide of indium-gallium-zinc-oxide (IGZO), indium-gallium-tin-oxide (IGO), and indium-gallium-oxide (IGO) may be included.

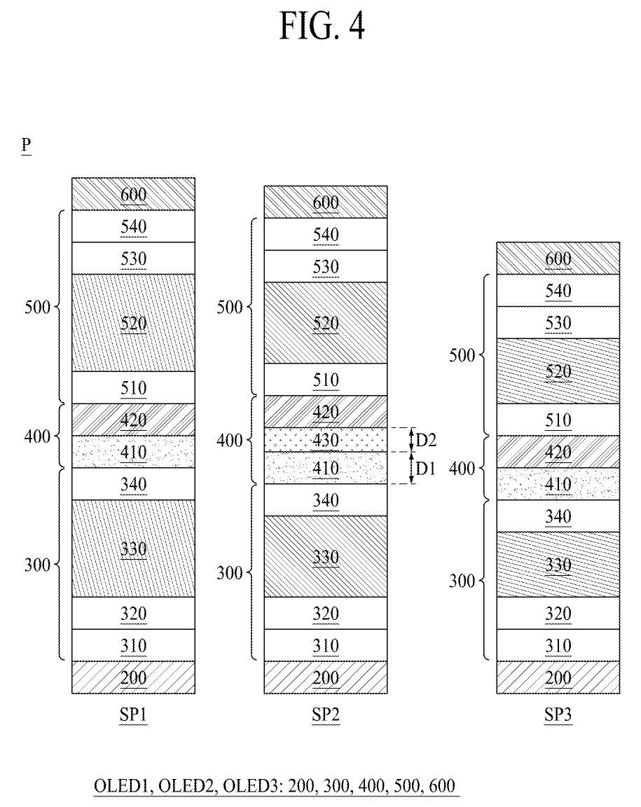

To insulate the gate electrode 121 from the semiconductor layer 122, the gate insulating layer 123 may be disposed between the gate electrode 121 and the semiconductor layer 122. The gate insulating layer 123 may be composed of a single layer of silicon nitride (SiNx) or silicon oxide (SiOx), or multiple layers thereof. In addition, FIG. 4 illustrates a bottom gate structure in which the semiconductor layer 122 is disposed on the gate electrode 121, but is not limited thereto. For example, a top gate structure in which the gate electrode 121 is disposed on the semiconductor layer 122 may be disclosed.

The source electrode 124 and the drain electrode 125 may be disposed on the semiconductor layer 122 while facing each other. In addition, the passivation layer 130 may be disposed on the source electrode 124 and the drain electrode 125. A contact hole exposing a portion of the drain electrode 125 may be formed in the passivation layer 130. In addition, the passivation layer 130 may be formed of an inorganic insulating material such as silicon oxide (SiOx), silicon nitride (SiNx), silicon oxynitride (SiOxNy), or the like.

The planarization layer 140 may be disposed on the thin film transistor 120. The planarization layer 140 may compensate for a step difference caused by the thin film transistor 120 to planarize an upper area of the thin film transistor 120. In addition, the planarization layer 140 may be formed of an organic insulating material such as an acrylic resin, an epoxy resin, a phenolic resin, a polyamide resin, or a polyimide resin.

The bank 150 may be disposed on the planarization layer 140 and in the non-emission area NEA. The bank 150 may expose a partial area of the planarization layer 140.

The bank 150 may include an organic insulating material such as an acrylic resin, an epoxy resin, a phenolic resin, a polyamide resin, a polyimide resin, etc. Alternatively, the bank 150 may include an inorganic insulating material such as silicon oxide (SiOx), silicon nitride (SiNx), silicon oxynitride (SiOxNy), etc. In this case, the bank 150 may further include a material absorbing light. For example, the bank 150 may be a black bank.

The light emitting device OLED may be disposed on the planarization layer 140. The light emitting device OLED may include a first electrode 200, a first stack 300, a charge generation layer 400, a second stack 500, and a second electrode 600.

The first electrode 200 may be disposed on the planarization layer 140 exposed by the bank 150. An end of the first electrode 200 may be covered by the bank 150. In addition, the first electrode 200 may function as an anode of the display device. That is, the first electrode 200 may provide holes to the first stack 300.

The first electrode 200 may be electrically connected to the thin film transistor 120 through a contact hole disposed in the passivation layer 130 and the planarization layer 140. FIG. 3 illustrates that the first electrode 200 is electrically connected to the drain electrode 125, but is not limited thereto. For example, the first electrode 200 may be electrically connected to the source electrode 124.

The first electrode 200 may include a transparent conductive material such as indium tin oxide (ITO) or indium zinc oxide (IZO). Alternatively, the first electrode 200 may include a metal material such as aluminum (Al), silver (Ag), copper (Cu), molybdenum (Mo), titanium (Ti), tungsten (W), or chromium (Cr), or an alloy thereof. Furthermore, the first electrode 200 is illustrated as a single layer, but may be formed as multiple layers.

The first stack 300 may be disposed on the first electrode 200. The first stack 300 may also be disposed on the bank 150. That is, the first stack 300 may be disposed in the emission area EA and the non-emission area NEA.

The first stack 300 may include a light emitting layer that generates light and a material layer for assisting the light emitting layer to generate light. A detailed description thereof will be described with reference to FIG. 4.

The charge generation layer 400 may be disposed on the first stack 300. Like the first stack 300, the charge generation layer 400 may also be disposed on the bank 150. That is, the charge generation layer 400 may be disposed in the emission area EA and the non-emission area NEA.

The charge generation layer 400 may provide electrons to the first stack 300 or holes to the second stack 500. A detailed description thereof will be described with reference to FIG. 4.

The second stack 500 may be disposed on the charge generation layer 400. The second stack 500 may also be disposed on the bank 150. That is, the second stack 500 may be disposed in the emission area EA and the non-emission area NEA.

The second stack 500 may include a light emitting layer that generates light and a material layer for assisting the light emitting layer to generate light. A detailed description thereof will be described with reference to FIG. 4.

The second electrode 600 may be disposed on the second stack 500. The second electrode 600 may also be disposed on the bank 150. That is, the second electrode 600 may be disposed in the emission area EA and the non-emission area NEA.

The second electrode 600 may function as a cathode of the display device. That is, the second electrode 600 may provide electrons to the second stack 500.

Since the display device according to an embodiment of the present disclosure is configured in a top emission type, the second electrode 600 may include a transparent conductive material such as an indium tin oxide (ITO) or an indium zinc oxide (IZO) to transmit light emitted from the first stack 300 and the second stack 500 upward.

FIG. 4 is a cross-sectional view of a light emitting device OLED according to an embodiment of the present disclosure.

The light emitting device OLED may be disposed in each of the first sub-pixel SP1, the second sub-pixel SP2, and the third sub-pixel SP3. A first light emitting device OLED1 may be disposed in the first sub-pixel SP1, a second light emitting device OLED2 may be disposed in the second sub-pixel SP2, and a third light emitting device OLED3 may be disposed in the third sub-pixel SP3.

As described above, each of the first to third light emitting devices OLED1 to OLED3 may include a first electrode 200, a first stack 300, a charge generation layer 400, a second stack 500, and a second electrode 600.

The first electrode 200 is disposed on the substrate 100 and may be disposed in each of the first to third subpixels SP1 to SP3. The first electrode 200 may provide holes to the first stack 300. In addition, the first electrodes 200 of the first to third light emitting devices OLED1 to OLED3 include the same material and may have the same thickness, but are not limited thereto.

The first stack 300 of each of the first to third light emitting devices OLED1 to OLED3 may be disposed on the first electrode 200. In addition, the first stack 300 of each of the first to third light emitting devices OLED1 to OLED3 may include a first hole injection layer 310, a first hole transport layer 320, a first light emitting layer 330, and a first electron transport layer 340.

In the first to third light emitting devices OLED1 to OLED3, the first hole injection layer 310 is disposed on the first electrode 200, and may assist holes provided in the first electrode 200 to be easily injected into the first light emitting layer 330. In addition, the first hole injection

layer 310 of the first to third light emitting devices OLED1 to OLED3 includes the same material and may be formed to have the same thickness, but is not limited thereto.

In the first to third light emitting devices OLED1 to OLED3, the first hole transport layer 320 is disposed on the first hole injection layer 310, and may assist the holes provided in the first electrode 200 to be easily transported to the first light emitting layer 330. In addition, the first hole transport layer 320 of the first to third light emitting devices OLED1 to OLED3 includes the same material and may be formed to have the same thickness, but is not limited thereto.

In the first to third light emitting devices OLED1 to OLED3, the first light emitting layer 330 may be disposed on the first hole transport layer 320. The first light emitting layer 330 of the first light emitting device OLED1 may generate a red light, the first light emitting layer 330 of the second light emitting device OLED2 may generate a green light, and the first light emitting layer 330 of the third light emitting device OLED3 may generate a blue light.

In order to implement micro-cavity characteristics, a thickness of the first light emitting layer 330 of the third light emitting device OLED3 may be smaller than thickness of the first light emitting layer 330 of the first and second light emitting devices OLED1 and OLED2, but is not limited thereto.

In the first to third light emitting devices OLED1 to OLED3, the first electron transport layer 340 may be disposed on the first light emitting layer 330 to assist the easily transport of electrons provided from the charge generation layer 400 to the first light emitting layer 330. In addition, the first electron transport layer 340 of the first to third light emitting devices OLED1 to OLED3 includes the same material and may be formed to have the same thickness, but is not limited thereto.

In the first to third light emitting devices OLED1 to OLED3, the charge generation layer 400 is disposed on the first electron transport layer 340, and may include an n-type charge generation layer 410 and a p-type charge generation layer 420.

In the first to third light emitting devices OLED1 to OLED3, the n-type charge generation layer 410 is disposed on the first electron transport layer 340 and may provide electrons to the first stack 300. In addition, the n-type charge generation layer 410 of the first to third light emitting devices OLED1 to OLED3 includes the same material and may be formed to have the same thickness, but is not limited thereto.

In the first to third light emitting devices OLED1 to OLED3, the p-type charge generation layer 420 is disposed on the n-type charge generation layer 410 and may provide holes to the second stack 500. In addition, the p-type charge generation layer 420 of the first to third light emitting devices OLED1 to OLED3 includes the same material and may be formed to have the same thickness, but is not limited thereto.

In this case, the second light emitting device OLED2 may further include an auxiliary charge generation layer 430. Although FIG. 4 illustrates that the auxiliary charge generation layer 430 is disposed in the second light emitting device OLED2 and is not disposed in the first light emitting device OLED1 and the third light emitting device OLED3, the present disclosure is not limited thereto. For example, any one of the first light emitting device OLED1 and the third light emitting device OLED3 may further include an auxiliary charge generation layer 430.

The auxiliary charge generation layer 430 may be disposed between the n-type charge generation layer 410 and the p-type charge generation layer 420.

The auxiliary charge generation layer 430 may perform the same function as the n-type charge generation layer 410. That is, like the n-type charge generation layer 410, the auxiliary charge generation layer 430 may provide electrons to the first stack 300.

The n-type charge generation layer 410 and the auxiliary charge generation layer 430 may include an n-type host material and an n-type dopant material.

The n-type host material may include an organic material capable of transferring electrons. For example, the n-type host material may include, but is not limited to, tris(8-hydroxyquinolino)aluminum), Liq(8-hydroxyquinolino-lithium), PBD(2-(4-biphenyllyl)-5-(4-tert-butylphenyl)-1,3,4oxadiazole), TAZ(3-(4-biphenyl)4-tert-butylphenyl-1,2-triazole), spiro-PBD, and bis(2-methyl-8-quinolinate)-4-(phenylphenylphenolato)aluminum), SAlq, TPBi(2,2-(2,2-(1,3,5-benzenetriyl)-tris(1-phenyl-1-H-benzimidazole), oxadiazole, triazole, phenanthroline, benzoxazole or benzthiazole.

The n-type dopant material may include a metal material. Specifically, the n-type dopant material may include an alkali metal. For example, the n-type dopant material may include any one of lithium (Li), sodium (Na), potassium (K), or cesium (Cs), but is not limited thereto. Alternatively, the n-type dopant material may include an alkaline earth metal. For example, the n-type dopant material may include any one of magnesium (Mg), strontium (Sr), barium (Ba), radium (Ra), or ytterbium (Yb), but is not limited thereto.

An electrical conductivity of the n-type charge generation layer 410 and the auxiliary charge generation layer 430 may be adjusted by the n-type dopant material. For example, the n-type dopant material of the n-type charge generation layer 410 and the n-type dopant material of the auxiliary charge generation layer 430 may be the same metal material. In this case, the electrical conductivity of the n-type charge generation layer 410 and the auxiliary charge generation layer 430 may be adjusted by adjusting doping concentrations of the n-type charge generation layer 410 and the auxiliary charge generation layer 430. Specifically, the doping concentration of the n-type charge generation layer 410 and the auxiliary charge generation layer 430 may be different from each other. In particular, the doping concentration of the n-type charge generation layer 410 may be lower than the doping concentration of the auxiliary charge generation layer 430. That is, the electrical conductivity of the n-type charge generation layer 410 may be lower than the electrical conductivity of the auxiliary charge generation layer 430.

Alternatively, the n-type dopant material of the n-type charge generation layer 410 and the n-type dopant material of the auxiliary charge generation layer 430 may be different from each other. Since electrical conductivity is different according to a type of metal material, the electrical conductivity of the n-type charge generation layer 410 and the auxiliary charge generation layer 430 may be different from each other. That is, the electrical conductivity of the n-type charge generation layer 410 and the auxiliary charge generation layer 430 may be adjusted by configuring the n-type charge generation layer 410 and the auxiliary charge generation layer 430 to include different metal materials. In particular, the electrical conductivity of the n-type dopant material of the n-type charge generation layer 410 may be lower than that of the n-type dopant material of the auxiliary charge generation layer 430.

Thicknesses of the n-type charge generation layer 410 and the auxiliary charge generation layer 430 may be different from each other. In particular, a thickness D1 of the n-type charge generation layer 410 may be greater than a thickness D2 of the auxiliary charge generation layer 430. For example, the thickness D2 of the auxiliary charge generation layer 430 may be 1 nm to 10 nm.

In the first to third light emitting devices OLED1 to OLED3, the second stack 500 may be disposed on the p-type charge generation layer 420. In addition, the second stack 500 of each of the first to third light emitting devices OLED1 to OLED3 may include a second hole transport layer 510, a second light emitting layer 520, a hole block layer 530, and a second electron transport layer 540.

In the first to third light emitting devices OLED1 to OLED3, the second hole transport layer 510 is disposed on the p-type charge generation layer 420, and may assist the holes provided in the p-type charge generation layer 420 to be easily transported to the second light emitting layer 520. Furthermore, the second hole transport layer 510 of the first to third light emitting devices OLED1 to OLED3 includes the same material and may be formed to have the same thickness, but is not limited thereto. Furthermore, the second hole transport layer 510 includes the same material as the first hole transport layer 320, but is not limited thereto.

In the first to third light emitting devices OLED1 to OLED3, the second light emitting layer 520 may be disposed on the second hole transport layer 510. The second light emitting layer 520 of the first light emitting device OLED1 may generate a red light, the second light emitting layer 520 of the second light emitting device OLED2 may generate a green light, and the second light emitting layer 520 of the third light emitting device OLED3 may generate a blue light.

In order to implement micro-cavity characteristics, a thickness of the second light emitting layer 520 of the third light emitting device OLED3 may be smaller than a thickness of the second light emitting layer 520 of the first and second light emitting devices OLED1 and OLED2, but is not limited thereto.

In the first to third light emitting devices OLED1 to OLED3, the hole block layer 530 may be disposed on the second light emitting layer 520. The hole block layer 530 prevents holes injected into the second light emitting layer 520 from leaking through the second electron transport layer 540, and thus improves a coupling between holes and electrons in the second light emitting layer 520, thereby improving a light emitting efficiency of the second light emitting layer 520.

In the first to third light emitting devices OLED1 to OLED3, the second electron transport layer 540 may be disposed on the hole block layer 530 to assist easily transport of electrons provided from the second electrode 600 to the second light emitting layer 520. In addition, the second electron transport layer 540 of the first to third light emitting devices OLED1 to OLED3 includes the same material and may be formed to have the same thickness, but is not limited thereto.

In the first to third light emitting devices OLED1 to OLED3, the second electrode 600 is disposed on the second stack 500 and may be disposed in each of the first to third subpixels SP1 to SP3. The second electrode 600 may provide electrons to the second stack 500.

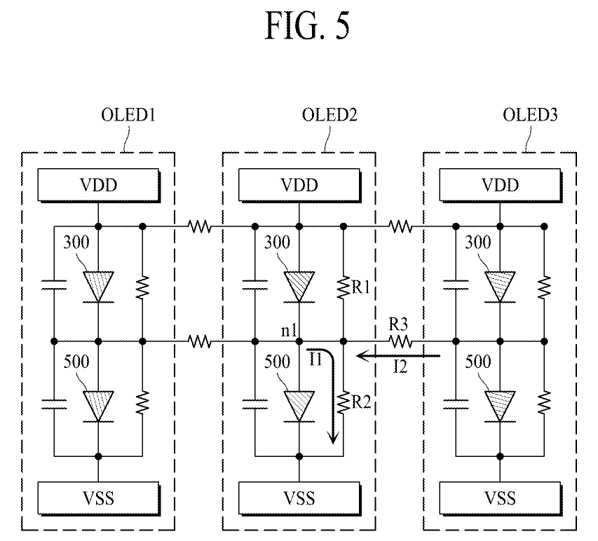

FIG. 5 is a circuit diagram of a light emitting device OLED according to an embodiment of the present disclosure.

Generally, when a voltage is supplied to the first electrode 200 and the second electrode 600, a driving current may flow from the first electrode 200 to the second electrode 600. The first stack 300 and the second stack 500 may generate light by the driving current, and the light emitting device OLED may emit light. In this case, a lateral leakage current LLC may flow between adjacent sub-pixels SP.

Referring to FIG. 5, a first power voltage VDD may be a voltage applied to the first electrode 200, and a second power voltage VSS may be a voltage applied to the second electrode 600. The first light emitting layer 330 of the first stack 300 and the second light emitting layer 520 of the second stack 500 may generate light by the first power voltage VDD and the second power voltage VSS.

In this case, a resistance may occur in the light emitting device OLED due to each material layer of the light emitting device OLED. Specifically, in the second light emitting device OLED2, a first resistor R1 may occur due to the first stack 300, and a second resistor R2 may occur due to the second stack 500. In this case, due to the asymmetry between the first resistor R1 and the second resistor R2, a first leakage current I1 may flow. The first leakage current I1 may flow from a first node n1 to the second electrode 600. Accordingly, a color loss phenomenon may occur in the second light emitting device OLED2. In this case, the first node n1 may correspond to the n-type charge generation layer 410 having high electrical conductivity.

Alternatively, a resistance may occur between the adjacent light emitting devices OLED. Specifically, a third resistance R3 may occur between the second light emitting device OLED2 and the third light emitting device OLED3. A resistance of a horizontal electric field between the second light emitting device OLED2 and the third light emitting device OLED3 may be lower than a resistance of a vertical direction electric field of the second light emitting device OLED2. Accordingly, a second leakage current I2 may flow due to the third resistance R3. The second leakage current I2 may flow from the third light emitting device OLED3 to the second light emitting device OLED2.

Particularly, due to the high electrical conductivity of the n-type charge generation layer 410, when a low current is applied to implement a low gray scale, the second leakage current I2 may flow more easily. Accordingly, not only the light emitting device of the sub-pixel to which the voltage is applied, but also the light emitting device of the sub-pixel adjacent to the sub-pixel to which the voltage is applied may emit light. Referring to FIG. 5, when a voltage is applied to the third light emitting device OLED3, not only the third light emitting device OLED3 emits light, but also the second light emitting device OLED2 may emit light at the same time. Accordingly, light emission defects of sub-pixels may occur.

As described above, the first leakage current I1 and the second leakage current I2 are likely to occur as the electrical conductivity of the n-type charge generation layer 410 increases. Accordingly, in order to reduce the first leakage current I1 and the second leakage current I2, it may be preferable that the doping concentration of the n-type charge generation layer 410 is low.

However, as the doping concentration of the n-type charge generation layer 410 is lower, characteristics of the light emitting device OLED may be affected. For example, as the doping concentration of the n-type charge generation layer 410 is lower, a driving voltage of the light emitting device OLED may be higher. In addition, as the doping concentration of the n-type charge generation layer 410 is lower, a lifespan of the light emitting device OLED may be decreased. In addition, as the doping concentration of the n-type charge generation layer 410 is lower, a capacitance of the light emitting device OLED may be increased.

Accordingly, according to the present disclosure, by additionally forming the auxiliary charge generation layer 430, a generation of leakage current may be reduced and the characteristics of the light emitting device OLED may be improved. Specifically, by forming the doping concentration of the n-type charge generation layer 410 commonly disposed in the first to third light emitting devices OLED1 to OLED3 to be relatively low, the electrical conductivity of the n-type charge generation layer 410 may be reduced and the generation of leakage current may be reduced.

Meanwhile, since the auxiliary charge generation layer 430 having a relatively high doping concentration is formed only on a specific light emitting device OLED, the characteristics of the light emitting device OLED may be improved. In particular, the auxiliary charge generation layer 430 may be formed on the light emitting device OLED disposed in the green sub-pixel which has the greatest influence on the light emitting efficiency of the display device.

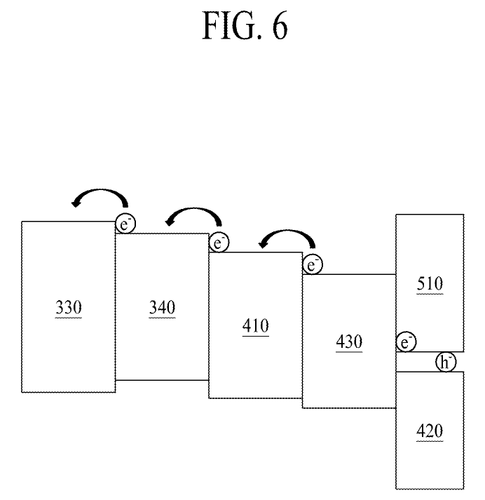

FIG. 6 is a diagram illustrating an energy band diagram of a light emitting device according to an embodiment of the present disclosure. In particular, it illustrates an energy band diagram of the second light emitting device OLED2.

Referring to FIG. 6, the first electron transport layer 340, the n-type charge generation layer 410, the auxiliary charge generation layer 430, and the p-type charge generation layer 420 may be disposed in order. A LUMO level may be increased in the order of the auxiliary charge generation layer 430, the n-type charge generation layer 410, and the first electron transport layer 340. That is, the LUMO level of the n-type charge generation layer 410 may be higher than the LUMO level of the auxiliary charge generation layer 430, and the LUMO level of the first electron transport layer 340 may be higher than the LUMO level of the n-type charge generation layer 410.

At this time, the Lowest Unoccupied Molecular Orbital (LUMO) level is compared as a negative value itself, not an absolute value, and the fact that A’s LUMO level is higher than B’s LUMO level means that A’s LUMO level absolute value is less than B’s LUMO level absolute value.

By a stepwise rise in the LUMO level of the auxiliary charge generation layer 430, the n-type charge generation layer 410, and the first electron transport layer 340, electrons may be transferred along the LUMO level of the auxiliary charge generation layer 430, the n-type charge generation layer 410, and the first electron transport layer 340 which are arranged sequentially.

In this case, the difference between the LUMO level of the first electron transport layer 340 and the LUMO level of the n-type charge generation layer 410 may be minimized by forming the doping concentration of the auxiliary charge generation layer 430 to be higher than the doping concentration of the n-type charge generation layer 410.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a first sub-pixel and a second sub-pixel;
a first light emitting device in the first sub-pixel; and
a second light emitting device in the second sub-pixel,
wherein each of the first light emitting device and the second light emitting device includes:
a first electrode on the substrate;
a first stack on the first electrode;
an n-type charge generation layer on the first stack; and
a p-type charge generation layer on the n-type charge generation layer, and
wherein the first light emitting device further includes an auxiliary charge generation layer between the n-type charge generation layer and the p-type charge generation layer.

2. The display device of claim 1, wherein the n-type charge generation layer of the first light emitting device and the n-type charge generation layer of the second light emitting device are continuously disposed, and
wherein the auxiliary charge generation layer is not disposed in the second sub-pixel.

3. The display device of claim 2, wherein the p-type charge generation layer of the first light emitting device and the p-type charge generation layer of the second light emitting device are continuously disposed,
wherein in the first light emitting device, a lower surface of the p-type charge generation layer is in contact with the auxiliary charge generation layer, and
wherein in the second light emitting device, a lower surface of the p-type charge generation layer is in contact with the n-type charge generation layer.

4. The display device of claim 1, wherein the n-type charge generation layer and the auxiliary charge generation layer provide electrons to the first stack.

5. The display device of claim 1, wherein the n-type charge generation layer and the auxiliary charge generation layer include an n-type host material and an n-type dopant material distributed in the n-type host material.

6. The display device of claim 5, wherein the n-type dopant material of the n-type charge generation layer and the n-type dopant material of the auxiliary charge generation layer are a same material.

7. The display device of claim 1, wherein a doping concentration of the n-type charge generation layer is different from a doping concentration of the auxiliary charge generation layer.

8. The display device of claim 7, wherein the doping concentration of the n-type charge generation layer is lower than the doping concentration of the auxiliary charge generation layer.

9. The display device of claim 1, wherein an electrical conductivity of the n-type charge generation layer is different from an electrical conductivity of the auxiliary charge generation layer.

10. The display device of claim 9, wherein the electrical conductivity of the n-type charge generation layer is lower than the electrical conductivity of the auxiliary charge generation layer.

11. The display device of claim 1, wherein a thickness of the n-type charge generation layer is greater than a thickness of the auxiliary charge generation layer.

12. The display device of claim 1, wherein a LUMO level of the n-type charge generation layer is higher than a LUMO level of the auxiliary charge generation layer.

13. The display device of claim 1, wherein the first light emitting device emits green light, and the second light emitting device emits red or blue light.

14. A display device of comprising:
a substrate;
a first electrode on the substrate;
a first stack on the first electrode;
an n-type charge generation layer on the first stack;
an auxiliary charge generation layer on the n-type charge generation layer;
a p-type charge generation layer on the auxiliary charge generation layer; and
a second stack on the p-type charge generation layer,
wherein the auxiliary charge generation layer has a higher doping concentration and a smaller thickness than the n-type charge generation layer.

15. The display device of claim 14, wherein the auxiliary charge generation layer and the n-type charge generation layer comprise different n-type host materials.
